(19) United States
(12) Patent Application Publication
(10) Pub. No.: US 2004/0068867 A1
(43) Pub. Date: Apr. 15, 2004

(54) Land-side mounting of components to an integrated circuit package

(76) Inventor: Edward Allyn Burton, Hillsboro, OR (US)

Correspondence Address: John C. Altmiller, KENYON & KENYON, 1025 Connecticut Avenue, N.W., Washington, DC, 20036, US

(21) Appl. No.: 10/272,075

(22) Filed: Oct. 15, 2002

(51) Int. Cl. H05K 3/30

(52) U.S. Cl. 29/832; 29/854

(57) ABSTRACT

A method and apparatus is presented to allow one or more electrical components to be coupled to the land-side of an integrated circuit package coupled to a circuit board. In a first embodiment, a void is provided in the circuit board, and a peripheral area of the integrated circuit package is coupled to a peripheral area around the void. This provides space for the insertion of components in the land-side of the integrated circuit package. In a second embodiment, a spacer is provided coupled to the peripheral area of the integrated circuit package to allow the insertion of components into the land-side of the package and above the circuit board. With these embodiments of the present invention, components, such as decoupling capacitors can be coupled closer to the die (e.g., a processor die) of the package thus reducing parasitic inductance.

### BACKGROUND OF THE INVENTION

The present invention pertains to the mounting of components to the land-side of an integrated circuit package. More particularly, the present invention pertains to the mounting of capacitors to the land-side area of an integrated circuit package, such as a processor, coupled to a printed circuit board or the like.

Integrated circuit (IC) packages have a number of different configurations known in the art. The purpose of an IC package is to enable the coupling of a die to electrical connectors which can then be coupled to other devices. For example, a die can be a silicon substrate upon which a plurality of electrical components (e.g., transistors, capacitors, resistors) and trace conductors are formed. In the typical IC package, electrically conductive prongs are physically attached to bonding pads in the die and then the die is encapsulated in plastic to protect these connections. In the final product, the prongs jut out from the plastic package and can be inserted into appropriate receiving holes in a printed circuit board, a breadboard, etc.

A more recent technology for creating an IC package comprises the taking of a die and electrically mounting it to a component referred in the art as a controlled collapse chip connection (CCCC or C4) package. The C4 package does not include metallic prongs as in the plastic encapsulated system. The top side of the C4 package is electrically coupled to conductive “bumps” on the die, and the bottom side of the C4 package includes an array of lands that are electrically coupled to the die through the C4 package. The bottom side of the C4 package is also referred to as the “land” side because this side is the situs for the lands conductively mounted to a printed circuit board (PCB) or the like.

An example of such a mounting is shown in FIG. 1. A die 11 is electrically connected to a C4 package 13. As stated above, the land-side of C4 package 13 includes an array of bonding areas, such as lands or solder balls to be electrically coupled to PCB 17. Examples of such arrays include the land-grid-array (LGA) and the ball-grid-array (BGA). The C4 package is electrically coupled to PCB 17 via a plurality of connectors 15.

As is known in the art, it may be desirable to electrically couple one or more capacitors to the die to provide decoupling capacitance to the die circuitry. The capacitance value for each of these capacitors tend to be relatively large (e.g., on the order of 10 μF). It is advantageous to place the decoupling capacitor as close as possible to the die to reduce parasitic inductance in series with these capacitors. In FIG. 1, several examples of how to couple such a capacitor to the die is shown. First, capacitors 20a and 20b are electrically coupled to the top side (or die-side) of the C4 package. There is a relatively large distance between the core or center of die 11 to capacitors 20a and 20b leading to a large inductance in series with the core of die 11. Also, coupling capacitors to die 11 is relatively expensive because the dimensions of C4 package 13 must be made larger so as to accommodate capacitors 20a and 20b (C4 package 13 has a high cost per unit area). Capacitors 22a, 22b located on the top side (or front side) of the printed circuit board are even farther from the center of die 11 leading to even larger inductance in the connection between die 11 and capacitors 22a-b.

Capacitors 24a, 24b can be coupled to the bottom (or back-side) of PCB 17, if PCB 17 provides electrical connections from the back-side of the board to C4 package 13. One example of such a PCB is a built-up multilayer (or high density multilayer) board sold by Ibiden USA Corp., and under the DYCOstrate® and TWINflex® marks by WürthElektronik GmbH (Rot am See, Germany). A second example would be one or more so-called “FR4” boards. An FR4 board includes an epoxy resin, reinforced with woven glass fibre cloth and treated to enhance its fire retardance. Each FR4 board includes a number of conductive traces on each side of the board with drilled plated through holes that connect traces on one side of the board to another. Though coupling capacitors 24a and 24b to the back-side of PCB 17 is less expensive than the coupling of capacitors 20a and 20b to C4 package 13, there is considerable parasitic inductance present in PCB 17, especially in an FR4 PCB. In all, the decoupling capacitor examples given above suffer the problems of extensive cost and/or high parasitic impedances.

Another approach is to provide very small capacitors coupled between connectors 15 and between C4 package 13 and PCB 17. Because of severe space restrictions in this area, only small capacitors can be used which may require additional capacitors to be placed on PCB 17 or C4 package 13 to achieve the desired decoupling effect.

In view of the foregoing electrical and cost problems with connecting components, such as decoupling capacitors to a die, there is a need for an improved method and apparatus for coupling components to a land-side of an IC package.

### SUMMARY OF THE INVENTION

According to a first embodiment of the present invention, a circuit board is provided that includes a void having a peripheral area around the void. An integrated circuit package is also provided having a land-side with a peripheral area adapted to be coupled to the peripheral area around the void of the circuit board. The land-side of the integrated circuit package is adapted to be coupled to an electrical component.

### BRIEF DESCRIPTION OF THE DRAWINGS

FIG. 1 is a side view of a C4 package mounted to a printed circuit board and the coupling of capacitors to these devices as is known in the art.

FIG. 2 is a cross-sectional side view of a C4 package mounted to a PCB according to an embodiment of the present invention.

FIG. 2A is a cross-sectional side view of the die, package and PCB of FIG. 2 showing an example of loop current through these devices.

FIG. 3 is a cross-sectional side view of a first alternative embodiment of the present invention for coupling a C4 package to a PCB where a spacer ring or the like is placed between the C4 package and the PCB.

FIG. 4 is a cross-sectional side view of a second alternative embodiment of the present invention for coupling a C4 package to a PCB where a PCB lamination is placed between the C4 package and the PCB.

FIG. 5 is a cross-sectional side view of a third alternative embodiment of the present invention for coupling a C4 package to a PCB where a socket-like contact is placed between the C4 package and the PCB.

### DETAILED DESCRIPTION

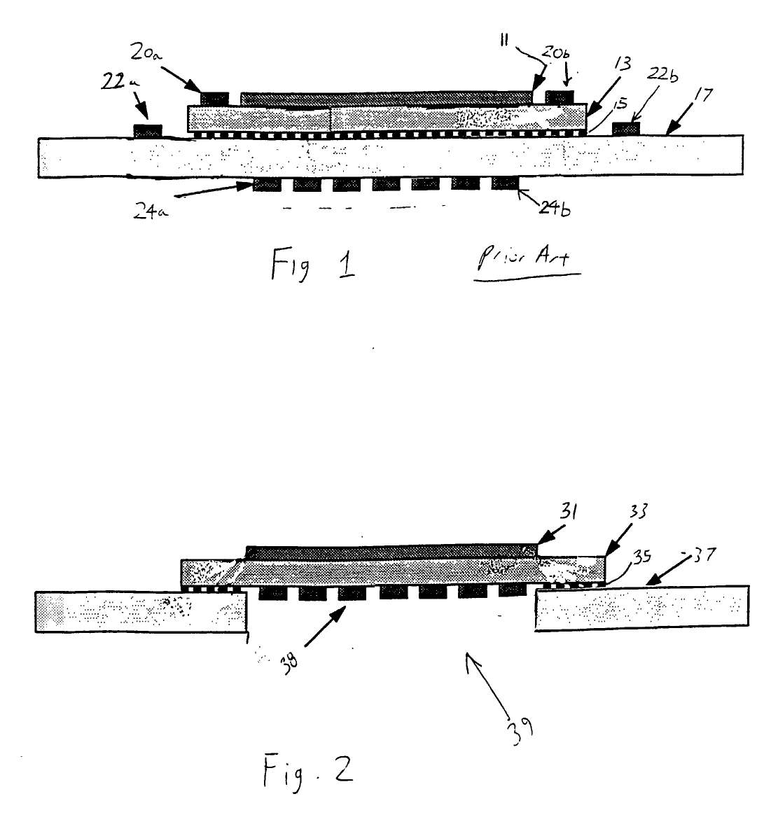

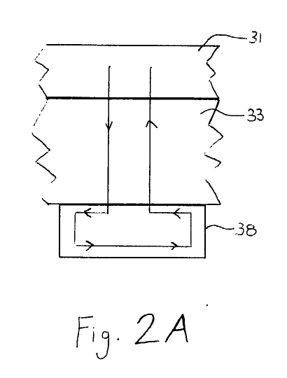

Referring to FIG. 2, an embodiment of the present invention is shown for coupling electrical components, such as capacitors to an IC package, such as a C4 package. Die 31 is coupled to a package, such as C4 package 33 in a known manner. Package 33 can then be coupled to PCB 37 via connectors 35 in an LGA or BGA manner, for example. In this embodiment of the present invention, PCB 37 is provided with a void 39. A peripheral area of package 33 is coupled to a peripheral area around void 39. Accordingly, an electrical component such as a decoupling capacitor 38 can be coupled directly to the land-side of package 33 either prior to or after package 33 is coupled to PCB 37 via connectors 35. Void 39 provides sufficient space under package 33 to allow decoupling capacitors (e.g., capacitor 38) of a sufficient size to be coupled to the land-side of package 33.

Coupling capacitors to the land-side of package 33 results in a substantial reduction in parasitic inductance in the circuit between die 31 and capacitor 38. As seen in FIG. 2A, the current flow from die 31 through package 33 and capacitor 39 and back to die 31 forms a relatively short loop where inductance in parallel sections of the loop tend to cancel each other out. In an example where the structure of FIGS. 2 and 2A are part of the Pentium® II processor (Intel Corporation), the total inductance in the loop of FIG. 2A is approximately 200 picohenrys. When placing decoupling capacitors on the bottom side of a typical FR4 PCB (e.g., capacitors 24a-b in FIG. 1), the parasitic inductance in the capacitor alone can be 450 picohenrys and the loop between die 11, package 13, PCB 17, capacitor 24a and back to die 11 can be 3500 picohenrys. Accordingly, in the embodiment of FIG. 2, there is over a 90% reduction in parasitic inductance in coupling capacitors to the land-side of package 33 as opposed to the bottom of the PCB.

Referring to FIGS. 3-5, alternative embodiments of the present invention are shown where a spacer is placed between a peripheral area of package 33 and PCB 37. The spacer defines an open area on the land-side of package 33 and is adapted to electrically couple package 33 to PCB 37. The spacer should have a sufficient height to allow electrical components to be coupled to the land-side of package 33 and above PCB 37. For example in the first alternative embodiment of FIG. 3, die 31 is electrically coupled to package 33, and one or more capacitors 38 are coupled to the land-side of package 33. Rather than including a void in PCB 37, a spacer ring 41 is provided to increase the distance between the land-side of package 33 and the top side of the PCB and is made of a sufficiently rigid material. In this example, spacer ring 41 is disposed around the peripheral area of package 33 and provides an electrical connection between connectors 35 and connectors 42. In this example, connectors 42 can be LGA or BGA connectors coupled to PCB 37.

A second alternative embodiment is shown in FIG. 4, where a PCB ring 44 is provided around the peripheral area of package 33. PCB ring 44 can be made with plated through holes that provide an electrical connection between the electrical bonding area of package 33 and connector 45, which in turn are coupled to PCB 37. As with the example of FIG. 3, PCB ring 44 raises package 33 from PCB 37 to provide more space between these devices for decoupling capacitors or the like.

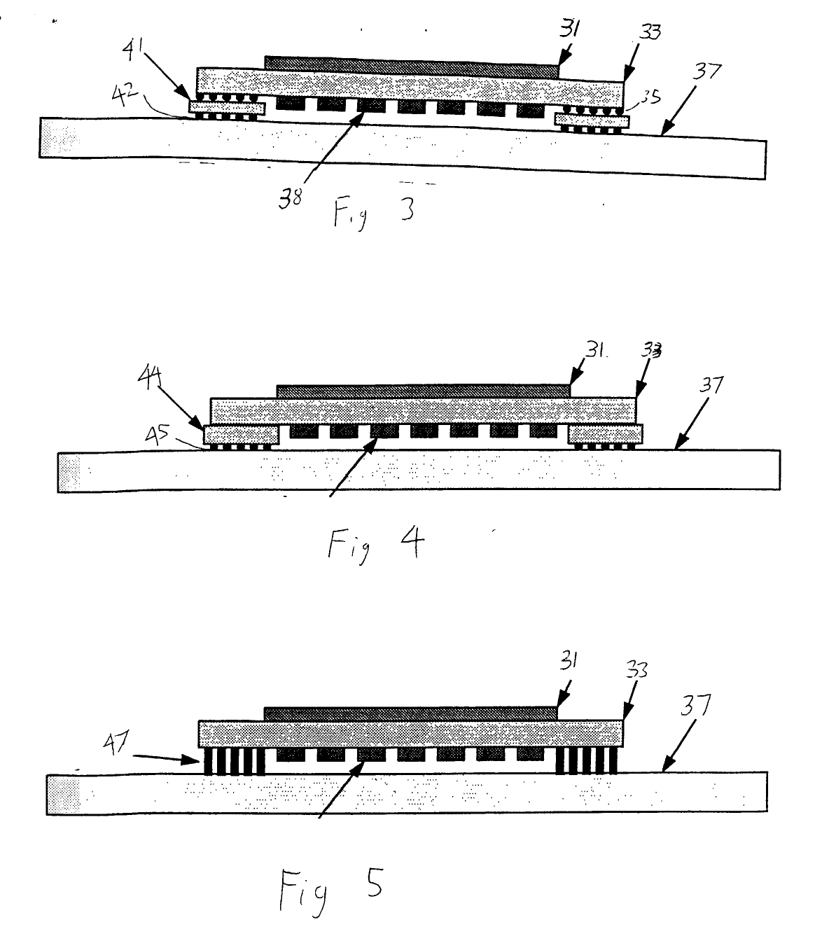

A third alternative embodiment is shown in FIG. 5, where elongated conductive pins 47 are disposed around the peripheral area of package 33 to electrically connect the land-side of package 33 with the top side of PCB 37. Pins 47 can be so-called pogo pins or other socket-like conductors that are placed in recessed regions in package 33 and PCB 37. As with the examples of FIGS. 3 and 4, pins 47 provide more space between the land side of package 33 and the top side of PCB 37 for the placement of electrical components such as decoupling capacitors.

Although several embodiments are specifically illustrated and described herein, it will be appreciated that modifications and variations of the present invention are covered by the above teachings and within the purview of the appended claims without departing from the spirit and intended scope of the invention. For example, in the Pentium® II product, the processor and other integrated circuits are coupled to a small cartridge substrate, which provides a single edge connector for coupling to the motherboard. Using the method and apparatus of the present invention, sufficient decoupling capacitors can be coupled to the processor package so that the processor package may be coupled to the motherboard without the intervening cartridge substrate.

What is claimed is:

1. An electronic circuit assembly, comprising:
a circuit board including a void having a peripheral area around said void; and
an integrated circuit package having a land-side with a peripheral area adapted to be coupled to the peripheral area around the void of said circuit board, the land-side of the integrated circuit package being adapted to couple to an electrical component.

2. The apparatus of claim 1 further comprising:
an electrical component coupled to the land-side of said integrated circuit package.

3. The apparatus of claim 2 wherein said electrical component is a capacitor.

4. The apparatus of claim 3 wherein said integrated circuit package includes a processor.

5. An electronic circuit assembly comprising:
an integrated circuit package having a land-side with a peripheral area; and
a spacer coupled to said peripheral area and defining an open area on the land-side of said integrated circuit package, said spacer adapted to electrically couple said integrated circuit package to a circuit board; and
wherein the land-side of said integrated circuit package is adapted to be coupled to an electrical component.

6. The apparatus of claim 5 wherein said spacer is a spacer ring.

7. The apparatus of claim 6 further comprising:
an electrical component coupled to the land-side of said integrated circuit package.

8. The apparatus of claim 7 wherein said electrical component is a capacitor.

9. The apparatus of claim 5 wherein said spacer is a printed circuit board ring.

10. The apparatus of claim 9 further comprising:
an electrical component coupled to the land-side of said integrated circuit package.

11. The apparatus of claim 9 wherein said electrical component is a capacitor.

12. The apparatus of claim 5 wherein said spacer includes a plurality of elongated pins.

13. The apparatus of claim 12 further comprising:
an electrical component coupled to the land-side of said integrated circuit package.

14. The apparatus of claim 13 wherein said electrical component is a capacitor.

15. The apparatus of claim 15 wherein said integrated circuit package includes a processor.

16. A method of forming an electronic circuit assembly comprising:
providing a void in said circuit board, said circuit board having a peripheral area around the void in said circuit board;
coupling a peripheral area of the land-side of an integrated circuit package to the peripheral area around the void of said circuit board; and
coupling at least one electrical component to the land-side of said integrated circuit package.

17. A method of forming an electronic circuit assembly comprising:
coupling at least one electrical component to the land-side of the integrated circuit package; and
coupling a spacer to a peripheral area of the land-side of the integrated circuit package.

18. The method of claim 17 further comprising:
coupling said integrated circuit package to a circuit board via a spacer.
